(19) United States
(12) Patent Application Publication
(10) Pub. No.: US 2010/0109155 A1
(43) Pub. Date: May 6, 2010

(54) RELIABLE INTERCONNECT INTEGRATION

(75) Inventors: Huang LIU, Singapore (SG); Johnny WIDODO, Singapore (SG); Yihua WANG, Singapore (SG); Wuping LIU, Singapore (SG); Ti OUYANG, Singapore (SG); Wei LU, Singapore (SG)

Correspondence Address: HORIZON IP PTE LTD, 7500A Beach Road, #04-306/308 The Plaza, SINGAPORE 199591, SG

(73) Assignee: Chartered Semiconductor Manufacturing, Ltd., Singapore (SG)

(21) Appl. No.: 12/265,714

(22) Filed: Nov. 5, 2008

(51) Int. Cl. H01L 23/52; H01L 21/768

(52) U.S. Cl. 257/734; 438/618; 257/E21.576; 257/E23.141

(57) ABSTRACT

A semiconductor device includes a dielectric layer in which an upper portion is densified. An interconnection is disposed in the dielectric layer. The densified portion reduces undercut during subsequent processing, improving reliability of the interconnection.

### BACKGROUND

The fabrication of integrated circuits (ICs) involves the formation of features on a substrate that make up circuit components, such as transistors, resistors and capacitors. The devices are interconnected, enabling the IC to perform the desired functions. Interconnections are formed by forming contacts and conductive lines in a dielectric layer using, for example, damascene techniques. A damascene structure, for example, includes a via or contact hole in a lower portion and a trench which is generally wider than the contact hole in an upper portion. The via serves as a contact to a device while the trench contains the conductive line for connecting the device to, for example, other devices.

As critical dimensions (CD) continue to shrink, ultra-low k dielectric (ULK) material have been proposed. However, the use of ULK has encountered integration problems, such as severed undercut in the etch profile.

From the foregoing discussion, it is desirable to improve integration of interconnects.

### SUMMARY

Embodiments generally relate to a semiconductor devices and methods of forming a semiconductor device. In one embodiment, a method for forming a semiconductor device is presented. The method includes providing a substrate prepared with a dielectric layer formed thereon. The dielectric layer is processed to form a densified portion on an upper portion of the dielectric layer. The method further includes forming an interconnection in the dielectric layer.

In one embodiment, a method for forming an interconnect is presented. The method includes providing a substrate. The substrate is prepared with a dielectric layer in which the interconnect is formed. The surface of the dielectric layer is treated to form a densified portion and the method further includes forming the interconnect in the dielectric layer.

A semiconductor device is presented in one embodiment. The semiconductor includes a substrate and a dielectric layer formed thereon. The dielectric layer includes a densified portion in an upper portion of the dielectric layer. An interconnection is disposed in the dielectric layer.

These and other objects, along with advantages and features of the present invention herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIGS. 1a-b show cross-sectional views of different embodiments of portions of a device; and

FIGS. 2a-f show a process for forming an embodiment of a device.

### DETAILED DESCRIPTION

Embodiments generally relates to devices, such as semiconductor devices or ICs. Other types of devices, such as micro electro-mechanical systems (MEMS), liquid crystal displays, are also useful. The ICs can be any type of IC, for example dynamic or static random access memories, signal processors, or system-on-chip devices. The ICs can be incorporated into, for example, consumer electronic products, such as computers, cell phones, and personal digital assistants (PDAs).

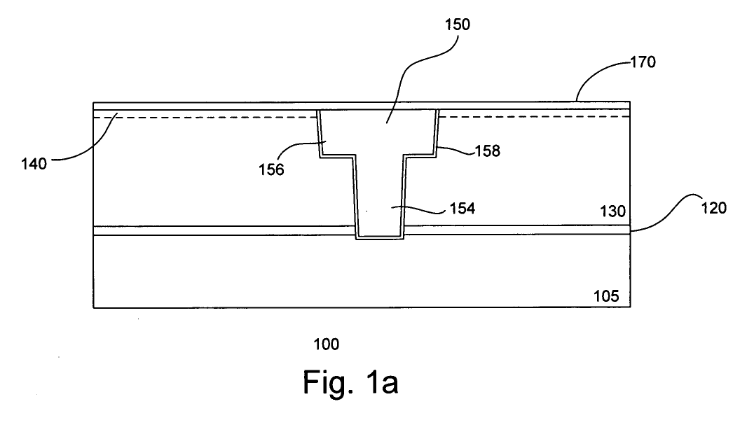

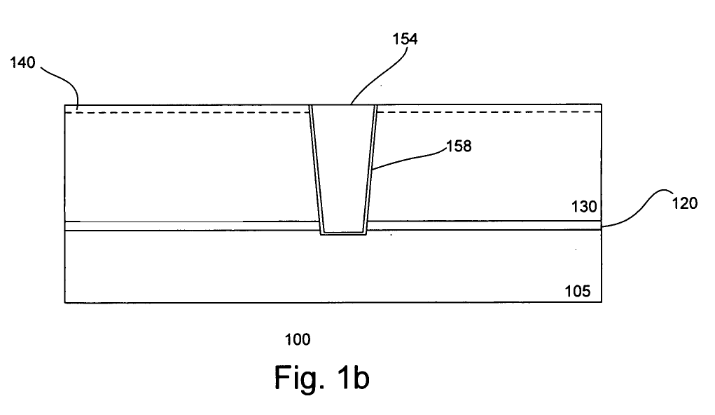

FIG. 1a shows an embodiment of a portion of a device, such as an integrated circuit (IC) 100. Other types of devices are also useful. As shown, the portion includes a substrate 105. The substrate, for example, comprises a silicon substrate. Other types of substrates, such as silicon germanium or silicon-on-insulator (SOI), are also useful. The substrate may include circuit components (not shown) such as transistors, capacitors, or resistors formed thereon. Other types of circuit components are also useful.

A dielectric layer 130 is disposed on the substrate. The dielectric layer, for example, serves as an interconnect dielectric (ICD) layer in which interconnects are formed. The interconnects provide the desired interconnections for the different circuit components. A lower etch stop layer 120 can be provided beneath the ICD layer. The lower etch stop layer can comprise various types of materials. In one embodiment, the lower etch stop layer comprises a dielectric material such as silicon nitride. Other types of etch stop materials can also be useful. For example, the lower etch stop layer can comprise, for example, silicon nitride. Other types of etch stop layers are also useful. The thickness of the lower etch stop layer can be about 250-500 Å. Other thicknesses are also useful.

The dielectric layer, in one embodiment, comprises a low-k or ultra low-k dielectric material. Various types of low-k or ultra low-k materials, such as organo-silicate glass (OSG) and fluorine-doped silicate glass (FSG), can be employed. Other types of dielectric materials are also useful. For example, the dielectric layer can comprise silicon oxide, doped silicon oxide such as fluorinated silicon oxide (FSG), undoped or doped silicate glasses such as boron phosphate silicate glass (BPSG) and phosphate silicate glass (PSG), undoped or doped thermally grown silicon oxide, undoped or doped TEOS deposited silicon oxide.

In one embodiment, the ICD includes lower and upper portions. The lower portion serves as an inter-level dielectric (ILD) layer while the upper portion serves as an intra-metal dielectric (IMD) layer. The dielectric layer can be a single layer or multi-layered stack. For example, a single layer can be used to serve as both the ILD and IMD or separate layers are used for the ILD and IMD. For multi-layered ICD, the ILD and IMD can comprise the same or different materials. In some cases, an etch stop layer can be disposed between the ILD and IMD. The ICD layer can represent any interconnect level of the device. For example, the ICD layer can be M1, M2, etc.

An interconnect 150 is formed in the ICD layer. The IC can include numerous interconnects. In one embodiment, the interconnect comprises a conductive line 156 in the upper portion or IMD while a contact 154 is disposed in the lower portion or ILD. The interconnect comprises a conductive material. For example, the conductive material can be any metal or alloy. In one embodiment, the interconnect may comprise copper, aluminum, tungsten, their alloys, or a combination thereof. It is understood that the contacts and conductive line can comprise the same or different materials. The contact couples the conductive line to contact a contact region below. Depending on the ICD level, the contact region can be another metal line or a device, such as a diffusion region or a gate of a transistor or a plate of a capacitor.

A barrier 158 can be provided to line the sidewalls and bottom of the interconnect. The barrier serves to protect the conductive line from diffusing into the dielectric layer. The barrier, for example, can comprise titanium nitride (TiN). Other types of barrier materials, such as TaN, tantalum, ruthenium or a combination thereof, including TiN, are also useful.

The conductive lines and/or contacts can be provided with slanted sidewalls. The slanted sidewall profile provides better sidewall barrier and seed coverage during processing. The slanted sidewalls, for example, comprise an angle of about 85-90°. Providing conductive lines and/or contacts with non-slanted sidewalls is also useful.

Alternatively, as shown in FIG. 1b, the dielectric layer includes a contact 154. The dielectric layer, for example, serves as a premetal dielectric (PMD) layer device. The dielectric layer can also be a via level of any of the metal levels of the device. The contact comprises a conductive material. For example, the conductive material can be any metal or alloy. In one embodiment, the contact can comprise copper, aluminum, tungsten, their alloys, or a combination thereof. In one embodiment, the contact comprises tungsten. A barrier 158 can be provided to line the sidewalls and bottom of the contact. The barrier, for example, can comprise titanium nitride (TiN). Other types of barrier materials, such as TaN, tantalum, ruthenium or a combination thereof, including TiN, are also useful.

In one embodiment, the dielectric layer comprises a densified portion 140. The densified portion, for example, is about 10-1000 Å thick. Other thicknesses are also useful. The densified portion comprises densified dopants. The densified dopants, for example, can be inert atoms such as helium (He), argon (Ar), neon (Ne), krypton (Kr), xenon (Xe), radon (Rn) or a combination thereof. In one embodiment, the densifying dopants comprise He atoms. Other types of densifying dopants may also be useful.

The densifying dopants are incorporated into the densified portion by a densifying process. In one embodiment, the densifying process comprises a surface treatment. The surface treatment, for example, may be a plasma treatment. The plasma treatment densifies the dielectric film by a physical sputtering mechanism. Other types of surface treatments may also be useful. For example, the surface treatment may include other types of plasma treatments, ion implantation, or physical sputtering processes. The densified portion, for example, reduces undercutting that can result during processing, such as ashing to remove photoresist prior to forming the interconnects.

In one embodiment, an etch stop layer 170 can be disposed over the surface of the dielectric layer. The etch stop layer covers the dielectric layer and top of the conductive line or contact. The etch stop layer, in one embodiment, comprises a dielectric material, such as silicon nitride. Other types of etch stop materials or techniques for forming the etch stop layer are also useful. The etch stop layer can also serve as a barrier layer to protect the conductive lines from oxidation. Additionally, it may also be used as an adhesion layer for subsequent layers deposited thereon.

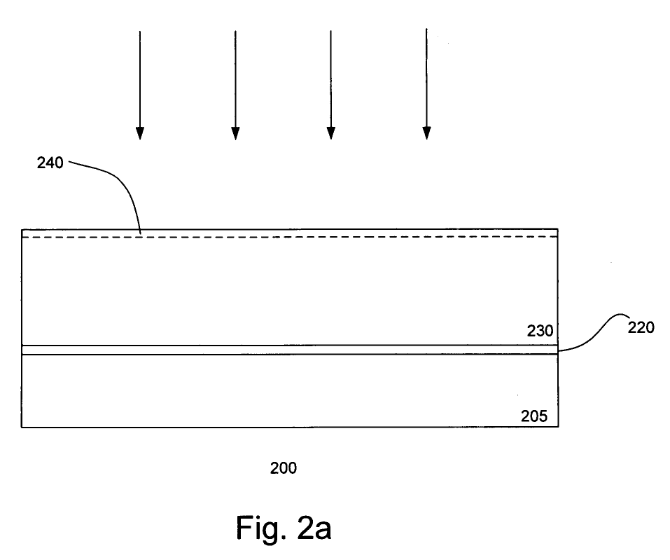

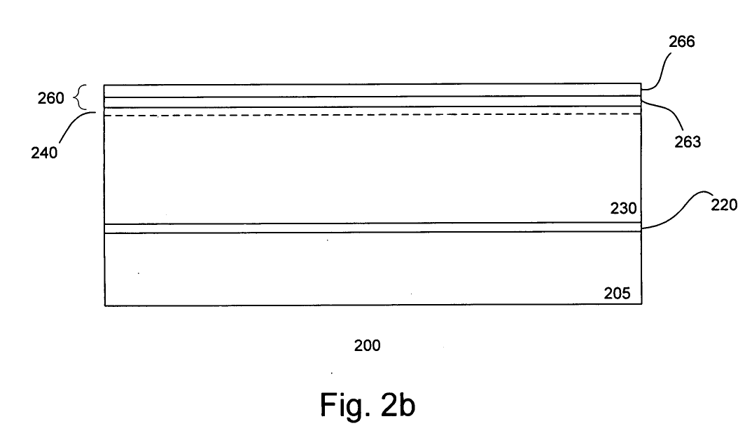

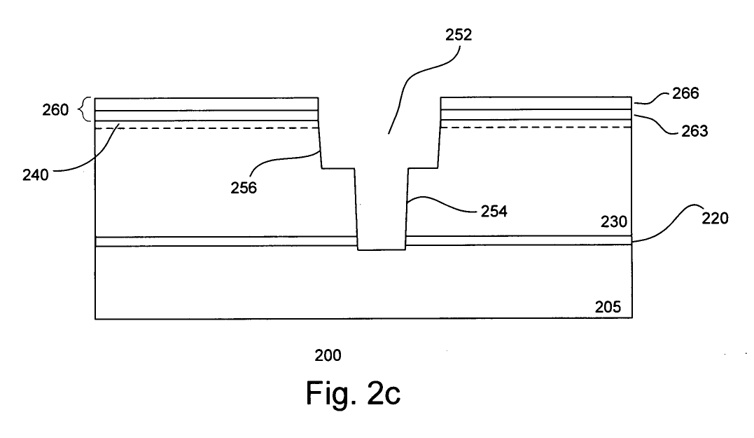

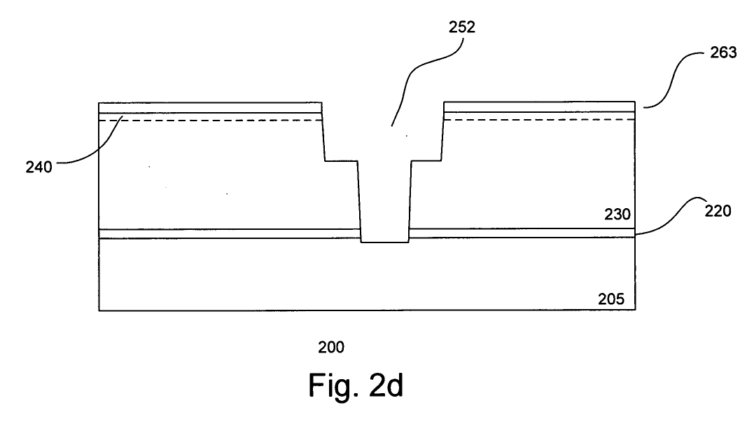

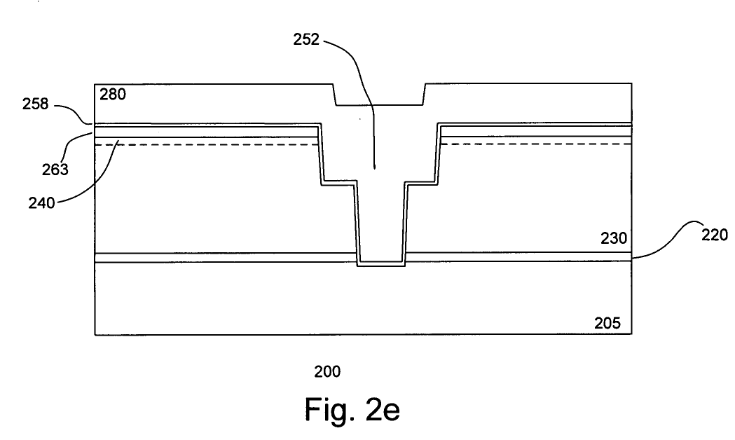

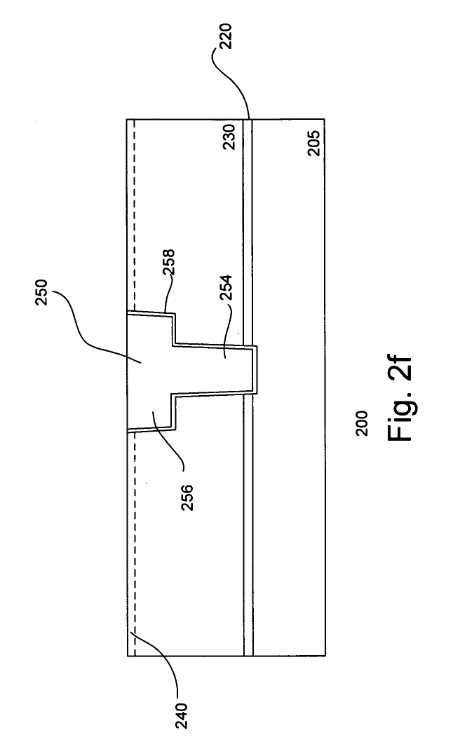

FIGS. 2a-f show a process for forming a portion 200 of a device, such as an IC in accordance with one embodiment. Referring to FIG. 2a, a substrate 205 is provided. The substrate, in one embodiment, comprises a p-type silicon substrate. Other types of substrates, such as a germanium-based, gallium arsenide, silicon-on-insulator (SOI), or sapphire substrate, are also useful. The substrate can be prepared with circuit components (not shown). Circuit components can include, for example, transistors, capacitors and/or resistors. Other types of circuit components are also useful.

The substrate is further prepared with dielectric layer 230. The dielectric layer, for example, serves as an ICD layer. A lower etch stop layer 220 can be provided beneath the ICD layer. The lower etch stop layer can comprise various types of materials. In one embodiment, the lower etch stop layer comprises a dielectric material such as silicon nitride. Other types of etch stop materials can also be useful. The thickness of the lower etch stop layer can be about 250-500 Å. Other thicknesses are also useful.

In one embodiment, the dielectric layer includes an upper or IMD portion and a lower or ILD portion. The dielectric layer can be a single layer or multi-layered stack. For example, a single layer can be used to serve as both the ILD and IMD or separate layers are used for the ILD and IMD. In some cases, an etch stop layer (not shown), such as silicon nitride, can be disposed between the ILD and IMD.

In one embodiment, the dielectric layer comprises a low-k or ultra low-k dielectric material. Various types of low-k or ultra low-k materials, such as organo-silicate glass (OSG) and fluorine-doped silicate glass (FSG), can be employed. Other types of dielectric materials are also useful. For example, the dielectric layer can comprise silicon oxide, doped silicon oxide such as fluorinated silicon oxide (FSG), undoped or doped silicate glasses such as boron phosphate silicate glass (BPSG) and phosphate silicate glass (PSG).

The ICD layer or layers can be deposited using various types of deposition techniques. For example, chemical vapor deposition (CVD) processes such as plasma enhanced (PECVD), high density (HDCVD), atmospheric pressure (APCVD) can be used. Other techniques such as spin-on processes are also useful. The specific process, for example, can depend on the type of material used and application.

The dielectric layer is processed after deposition. In one embodiment, at least the surface of the dielectric layer is processed. The processing densifies at least a surface portion of the dielectric layer. Preferably, the processing forms a densified portion 240 on the surface of the dielectric layer.

In one embodiment, the densifying process includes a surface treatment to incorporate densifying dopants into the surface of the dielectric layer. The surface treatment, for example, physically bombards the surface of the dielectric layer with densifying dopants. In one embodiment, the densifying dopants can be inert atoms, such as helium (He), argon (Ar), neon (Ne), krypton (Kr), xenon (Xe), radon (Rn) or a combination thereof. Other types of densifying dopants may also useful. In one embodiment, the densifying dopants comprise He atoms.

In one embodiment, the dopants are physically bombarded using an in-situ process. For example, the dopants, such as He, are incorporated using an in-situ plasma treatment. Incorporating other types or a combination of densifying dopants is also useful. The in-situ plasma process is performed for about 5-60 s in a temperature and pressure ranges of about 300-400° C. and 3-6 Torr, inert gas for example, He concentration of about 2000-10000 sccm and RF power of about 300-1000 W. The process parameters can be varied depending on the desired thickness and density of the densified dielectric layer. In alternative embodiment, other types of densifying processes may be employed. For example, the densifying process may include other types of plasma treatments, ion implantation, or physical sputtering processes.

The densified portion of the dielectric layer should be sufficiently dense and thick to avoid or reduce undercut during subsequent processing, such as ashing to remove photoresist. In one embodiment, the densified portion is about 10-1000 Å thick with density of about greater than 1.5 g/cc. Other thicknesses and density are also useful.

Referring to FIG. 2b, a mask layer 260 is formed over the dielectric layer. In one embodiment, the mask layer comprises multiple sub-mask layers. Providing a single mask layer is also useful. Other types of mask configurations are also useful. In one embodiment, the mask layer comprises a hard sub-mask layer 263 and a soft sub-mask layer 266. The hard sub-mask layer is deposited on the dielectric layer. The hard sub-mask layer, for example, comprises silicon nitride. Other types of hard mask materials, such as oxide, carbide or nitride are also useful. The hard sub-mask layer can be formed by, for example, coating or deposition techniques. Other techniques for forming the hard sub-mask layer are also useful. The hard mask layer is about 50-1000 Å thick. Other thicknesses are also useful.

Above the hard sub-mask layer is a soft sub-mask layer. In one embodiment, the soft sub-mask layer comprises photo-resist. The photo-resist, for example, can be formed by various techniques, such as spin-on. Other techniques are also useful. The thickness of the soft sub-mask layer is, for example, about 50-1000 Å. Other thicknesses are also useful. An anti-reflective coating (ARC) can be formed beneath the soft sub-mask layer. The ARC, for example, comprises organic materials with carbon chains. Other types of ARC layers are also useful.

In FIG. 2c, the dielectric layer is patterned using the mask to form an opening 252. To pattern the dielectric layer, the soft sub-mask can be first patterned using lithographic techniques. The pattern of the soft sub-mask is then transferred to the hard sub-mask using, for example, reactive ion etching (RIE). The mask is then used to pattern the dielectric layer. The dielectric layer can be patterned by, for example, RIE. Other techniques for patterning the dielectric are also useful.

In one embodiment, the opening comprises a dual damascene opening. The dual damascene opening, for example, comprises a via opening 254 in the ILD and a trench opening 256 in the IMD. The dual damascene opening can be formed using various techniques. For example, the dual damascene opening can be formed using via first or via last techniques. Alternatively, the opening can be a damascene opening. For example, the damascene opening can be a via opening. Providing other types of openings, such as trench openings, are also useful. As shown, the opening comprises slanted sidewalls. The slanted sidewalls, for example, comprise an angle of about 85-90°. Providing openings with non-slanted sidewalls is also useful.

The opening should be sufficiently deep to enable contact to a contact region below the dielectric layer. For example, the opening should be deeper than the etch stop layer 220 to ensure exposure of the contact region.

Referring to FIG. 2d, the photoresist or soft sub-mask layer is removed. The soft sub-mask is removed by, for example, ashing. Other techniques for removing the soft sub-mask are also useful. By providing a densified portion in the dielectric layer, undercut is reduced or prevented during removal of the sub-mask layer. This provides better CD and etch profile control, improving liner coverage in subsequent processing, thus reliability of the dielectric layer and/or the interconnect is enhanced.

As shown in FIG. 2e, a barrier 258 can be deposited on the substrate, lining the surface of the dielectric layer and opening. The barrier, for example, can comprise TiN. Other types of barrier materials, such as TaN, tantalum, ruthenium, are also useful. Providing a barrier layer having multiple layers is also useful. The barrier can be formed by, for example, PVD, CVD or atomic layer deposition (ALD). Other techniques for forming the barrier are also useful.

A conductive layer 280 is deposited on the substrate covering barrier and filling the dual damascene structure. The conductive material, for example, comprises copper, aluminum, tungsten, alloys such as Al doped Cu, Mn doped Cu, or a combination thereof. Other types of conductive materials, including metals and alloys, are also useful. In one embodiment, the conductive material comprises copper. The conductive material can be deposited by electro-plating. Other techniques, such as electro-less plating, CVD, PVD or sputtering, are also useful. The technique employed may depend on the material used.

Referring to FIG. 2f, excess material on the surface of the dielectric layer is removed to form an interconnection 250. In one embodiment, the excess material is removed by a planarizing process to form a planar surface with the top of the dielectric layer. For example, excess conductive and barrier materials on the surface of the ICD layer are removed by a polishing process, such as chemical mechanical polishing (CMP), electro-CMP (eCMP) or a combination thereof. Other types of planarizing or polishing processes are also useful. The polishing process may include multiple polishing steps to remove the different materials, such as conductive and barrier materials.

The densified portion of the dielectric layer is also more resistant to the polishing process. This advantageously reduces corrosion of the dielectric layer during polishing to form the interconnection.

By providing a densified portion in the upper portion of the dielectric layer, the k value of the dielectric may be minimally impacted or increased. However, if the increase in the k value is undesirable, the densified portion can be removed. For example, the densified portion can be removed by overpolishing during the process for forming the interconnection.

The process continues to form the IC. For example, additional processing can include forming more interconnect layers and interconnections, final passivation, dicing, assembly and packaging. Other processes are also useful.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A method for forming a semiconductor device comprising:
providing a substrate prepared with a dielectric layer formed thereon;
processing the dielectric layer to form a densified portion on an upper portion of the dielectric layer; and
forming an interconnection in the dielectric layer.

2. The method of claim 1 wherein processing the dielectric layer comprises providing physical bombardment in the upper portion of the dielectric layer.

3. The method of claim 2 wherein the physical bombardment comprises plasma treatment.

4. The method of claim 3 wherein the plasma treatment includes He, Ne, Ar, Kr, Xe or a combination thereof.

5. The method of claim 1 wherein processing the dielectric layer comprises in-situ plasma treatment.

6. The method of claim 1 wherein processing the dielectric layer comprises dopant implantation.

7. The method of claim 6 wherein the dopant implantation comprises He in the upper portion of the dielectric layer.

8. The method of claim 1 wherein the dielectric layer comprises low-k or ultra low-k dielectric materials.

9. The method of claim 8 wherein the processing of dielectric layer comprises providing physical bombardment in the upper portion of the low-k or ultra low-k dielectric layer.

10. The method of claim 9 wherein the physical bombardment comprises plasma treatment.

11. The method of claim 10 wherein the plasma treatment includes He, Ne, Ar, Kr, Xe or a combination thereof.

12. The method of claim 1 comprises providing a mask layer over the densified portion of the upper portion of the dielectric layer.

13. The method of claim 12 wherein the mask layer comprises a multiple sub-mask layer.

14. The method of claim 13 wherein the multiple sub-mask layer comprises a hard sub-mask layer and a soft sub-mask layer.

15. The method of claim 14 wherein the soft sub-mask layer comprises photoresist.

16. The method of claim 15 comprises patterning the dielectric layer to form an opening.

17. The method of claim 16 comprising removing the soft sub-mask layer by ashing.

18. The method of claim 17 wherein the densified portion on the upper portion of the dielectric layer is sufficiently thick and dense to reduce undercut during removing of the soft-sub-mask layer.

19. The method of claim 18 comprises providing a conductive layer on the substrate and fills the opening.

20. A method for forming an interconnect comprising:
providing a substrate, wherein the substrate is prepared with a dielectric layer in which the interconnect is formed;
treating the surface of the dielectric layer to form a densified portion; and
forming the interconnect in the dielectric layer.

21. A semiconductor device comprising:
a substrate;
a dielectric layer on the substrate, the dielectric layer comprises a densified portion in an upper portion of the dielectric layer; and
an interconnection disposed in the dielectric layer.
